(19) United States
(12) Patent Application Publication
(10) Pub. No.: US 2025/0113699 A1
(43) Pub. Date: Apr. 3, 2025

(54) TETRACHROMATIC PEROVSKITE IMAGE SENSOR AND METHOD FOR MANUFACTURING THE SAME

(71) Applicant: The Hong Kong University of Science and Technology, Hong Kong (CN)

(72) Inventors: Zhiyong FAN, Hong Kong (CN); Xiao QIU, Hong Kong (CN)

(21) Appl. No.: 18/894,030

(22) Filed: Sep. 24, 2024

Related U.S. Application Data
(60) Provisional application No. 63/587,148, filed on Oct. 1, 2023.

(51) Int. Cl. H10K 30/40; H10K 39/32

(52) U.S. Cl. CPC H10K 30/40; H10K 39/32

(57) ABSTRACT

A tetrachromatic perovskite image sensor includes a quartz layer, two perovskite p-i-n-i-p components, and two optical transparent electrodes. The first perovskite p-i-n-i-p component, on one side of the quartz layer, detects ultraviolet and blue light, with two photodetection layers corresponding to detection to ultraviolet and blue wavelength intervals. The second component, on the opposite side, detects green and red light, with layers for detecting green and red wavelength intervals. Optical transparent electrodes on both sides of the quartz layer apply bias collectively to both perovskite p-i-n-i-p components.

### TECHNICAL FIELD

The present invention generally relates to perovskite devices. More specifically, the present invention relates to tetrachromatic perovskite image sensors for detecting ultraviolet to visible lights and reproducing images by a stack design.

### BACKGROUND

For image sensing, avians experience a more colorful world than humans with their unique tetrachromatic eye, by which they broaden the visible spectrum to ultraviolet. In practical applications, tetrachromatic light sensors have usage in scenarios, especially, imagers with UV detection capability play vital roles in space exploration. However, integrating a tetrachromatic vision system in one device still poses significant challenges.

In the image sensor field, previous studies and products have merged RGB with one additional channel, such as emerald or near-infrared, for specialized applications like capturing detail in foliage, vegetation analysis, geological mapping, and environmental monitoring. However, limited work has been dedicated to constructing UVRGB imaging systems.

Limited colorful perovskite-integrated imaging systems are reported due to process compatibility and device miniaturization challenges. Existing strategies for constructing multiple-color perovskite photodetectors are parallel and stacking designs. Parallel structures necessitate a color filter array for monochromatic detection, which permanently reduces quantum efficiency, spatial resolution, and color accuracy. In contrast, devices without a colour filter array are unable to discriminate mixed lights in one pixel. Typical stacking architectures are based on multi-terminal tandem perovskite units, most of which are discrete devices, thus increasing both the cost and the complexity of processing, especially for the alignment.

Therefore, in the current development of perovskite sensors, there is a need for integrating colorful perovskite imaging systems in a single device.

### SUMMARY OF INVENTION

It is an objective of the present invention to provide methods and apparatuses to address the aforementioned shortcomings and unmet needs in the state of the art.

To overcome the bottlenecks, a highly pixelated UVRGB all-inorganic perovskite image sensor system with 4×32×32 pixels is presented, in which CsPbX₃ perovskites serve as the photosensitive layers and metal oxides serve as the charge transport layers. The four sequentially thermal-evaporated perovskite layers exhibit high crystallinity, low defect density, and long carrier lifetime. The thickness of each layer is carefully designed through optical simulations to achieve over 99.5% color selectivity while maintaining high light transmittance. A tandem dual-mode strategy is employed for the imagers to dispense with external filters and improve optical efficacy. The color space is further reconstructed with chromaticity for the UVRGB system to display color appearance, particularly with violet vectors. Importantly, the all-inorganic devices exhibit decent operational stability. The integrated tetrachromatic image sensor performs well under multiple harsh environments, demonstrating excellent imaging capability. This system is believed to hold promising potential for extravehicular detection applications.

In accordance with the first aspect of the present invention, a tetrachromatic perovskite image sensor is provided. The tetrachromatic perovskite image sensor includes a quartz layer, a first perovskite p-i-n-i-p component, a second perovskite p-i-n-i-p component, a first optical transparent electrode, and a second optical transparent electrode. The first perovskite p-i-n-i-p component is disposed on a first side of the quartz layer and is configured to detect ultraviolet and blue light, in which the first perovskite p-i-n-i-p component comprises two photodetection layers for detecting an ultraviolet wavelength interval and a blue wavelength interval, respectively. The second perovskite p-i-n-i-p component is disposed on a second side of the quartz layer and is configured to detect green and red light, in which the second perovskite p-i-n-i-p component comprises two photodetection layers for detecting a green wavelength interval and a red wavelength interval, respectively.

The first optical transparent electrode is disposed on the first side of the quartz layer. The second optical transparent electrode is disposed on the second side of the quartz layer, so as to apply bias to the first perovskite p-i-n-i-p component and second perovskite p-i-n-i-p component with the first optical transparent electrode collectively.

In accordance with the second aspect of the present invention, a tetrachromatic perovskite image sensor system is provided. The tetrachromatic perovskite image sensor system includes the tetrachromatic perovskite image sensor as afore-mentioned, at least one data collecting layer, and a power and communication layer. The data collecting layer is configured to capture and process output signals from the tetrachromatic perovskite image sensor and to convert them into digital data. The power and communication layer provides power supply and facilitates wireless data transmission to an external device for enabling remote control and monitoring, in which the digital data provided by the data collecting layer is transmitted to the external device by the power and communication layer.

In accordance with the third aspect of the present invention, a method for manufacturing a tetrachromatic perovskite image sensor is provided. The method includes steps as follows: providing an ITO-patterned quartz; forming a first photodetection layer for detecting a blue wavelength interval and a second photodetection layer for detecting a green wavelength interval on an upper side and a bottom side of the ITO-patterned quartz, respectively; forming a third photodetection layer for detecting an ultraviolet wavelength interval on the upper side of the ITO-patterned quartz after forming the first photodetection layer and the second photodetection layer; and forming a fourth photodetection layer for detecting a red wavelength interval on the bottom side of the ITO-patterned quartz after the forming the third photodetection layer, wherein the first photodetection layer, the second photodetection layer, the third photodetection layer, and the fourth photodetection layer are inorganic halide perovskites.

Device fabrication can be performed using the all-vacuum process flow. Regarding the design of tetrachromatic perovskite image sensor, there are at least four features:
1) device optical design: Parameters of four perovskite layers served as four ranges of wavelength photodetectors in one device, including thin films' thickness and wavelength ranges;
2) device electrical design: Two p-i-n-i-p stacking layers, pixelized electrodes array;
3) color discrimination and image reproduction; and
4) harsh environment working reliability.

### BRIEF DESCRIPTION OF DRAWINGS

Embodiments of the invention are described in more details hereinafter with reference to the drawings, in which:

FIG. 1A depicts a schematic exploded view of a tetrachromatic perovskite image sensor configured to detect ultraviolet to visible lights and reproduce images by a stacking design according to some embodiments of the present invention;

FIG. 1B shows a fabrication process of a tetrachromatic perovskite image sensor according to some embodiments of the present invention;

FIG. 2A shows a graph for transmittance simulation within the depth of an entirety of the tetrachromatic perovskite image sensor;

FIG. 2B, FIG. 2C, FIG. 2D, and FIG. 2E are graphs for transmittance simulation with respect to CsPbCl₃, CsPbClBr₂, CsPbBr₃, and CsPbBrI₂ thin films, respectively;

FIG. 3 shows a graph for the responsivity of the tetrachromatic perovskite image sensor as a function of wavelength according to some embodiments of the present invention;

FIG. 4 depicts a schematic drawing for energy level alignment of a tetrachromatic perovskite image sensor according to some embodiments of the present invention;

FIG. 5A and FIG. 5B illustrate the working mechanism of a tetrachromatic perovskite image sensor according to some embodiments of present invention;

FIG. 6 shows a graph for the responsivity of a tetrachromatic perovskite image sensor as a function of incident light intensity under 405 nm, 450 nm, 520 nm, and 635 nm light source according to some embodiments of the present invention;

FIG. 7A, FIG. 7B, FIG. 7C, and FIG. 7D show graphs for the response time of four photodetection layers;

FIG. 8 shows a graph for J-V characterizations of a tetrachromatic perovskite image sensor under dark and single wavelength illuminations according to some embodiment of the present invention;

FIG. 9A shows graphs for photocurrent response of mixed light source of 405 nm, 450 nm, 520 nm and 635 nm at forward and reverse working mode;

FIG. 9B shows graphs for the device's current density under dark and light conditions;

FIG. 10A illustrates the mixed light discrimination capability of the tetrachromatic perovskite image sensor system, with a tetrahedral light combination map based on 405 nm, 450 nm, 520 nm, and 635 nm light sources;

FIG. 10B shows the ternary light combination map, also based on 405 nm, 450 nm, 520 nm, and 635 nm light sources;

FIG. 10C displays the standard deviation of five maps, indicating the deviation between the actual and detected light combinations after calculation;

FIG. 11 illustrates a schematic diagram for a tetrachromatic perovskite image sensor system connected to a computer according some embodiments of the present invention;

FIG. 12 illustrates an image of a tetrachromatic perovskite image sensor system, in which the insert image is the device without read-out circuit; and

FIG. 13A and FIG. 13B show photographs and captured images of Earth (I), Neptune (II), Venus (III), flame (IV), and Crab Nebula (V) in ambient, vacuum, low temperature, high temperature, and vacuum environments.

### DETAILED DESCRIPTION OF THE INVENTION

In the following description, tetrachromatic perovskite image sensors and methods for manufacturing the same and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

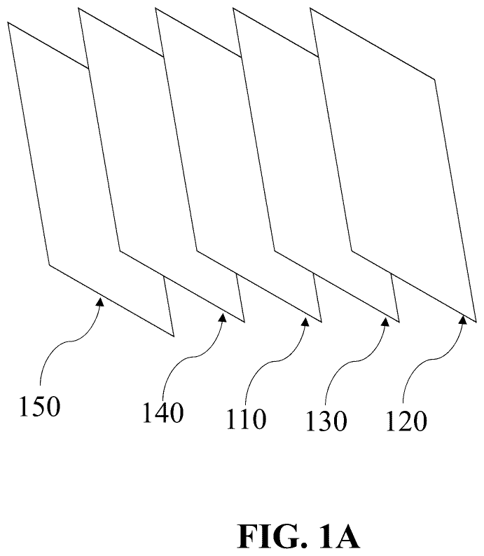

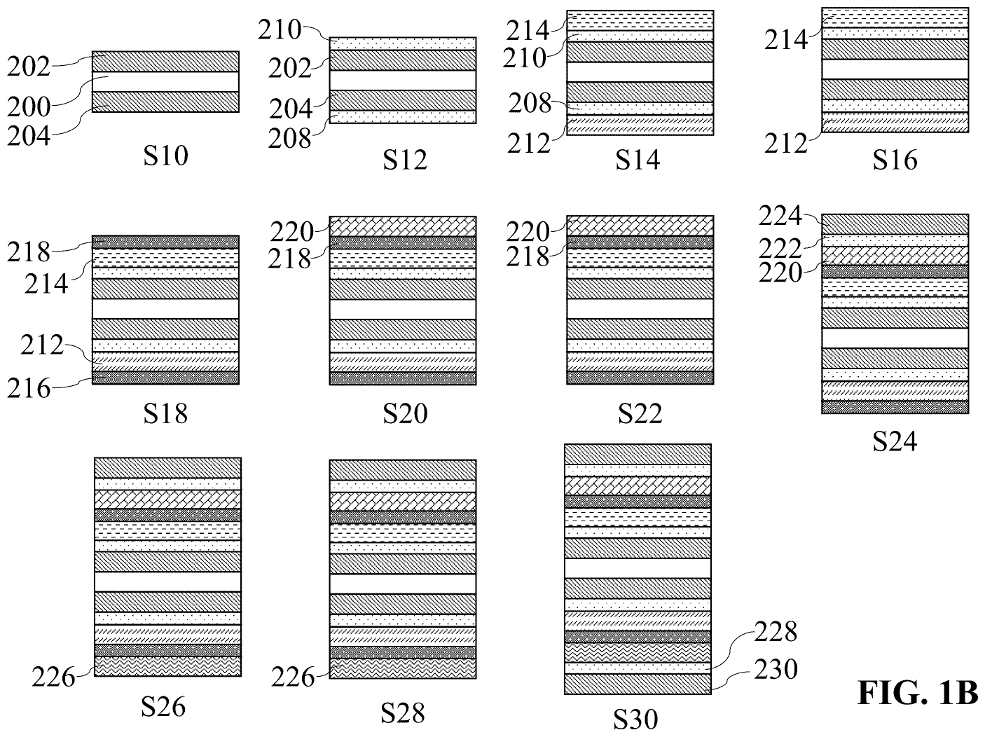

FIG. 1A depicts a schematic exploded view of a tetrachromatic perovskite image sensor 100 configured to detect ultraviolet to visible lights and reproduce images by a stacking design according to some embodiments of the present disclosure. The tetrachromatic perovskite image sensor 100 includes a thin quartz layer 110 that separates the device structure into two halves and photodetection layers 120, 130, 140, and 150. The photodetection layers 120 and 130 are for sensing ultraviolet and blue light on a front side of the thin quartz layer 110 for detecting short-wavelength light. The photodetection layers 140 and 150 are for sensing green and red light on a back side of the thin quartz layer 110 for sensing long-wavelength light. Specifically, for those two halves, each includes a p-i-n-i-p perovskite structures (p-i-n-i-p perovskite components). On the front side of the thin quartz layer 110, the optical component with the stacked photodetection layers 120 and 130 is configured to detect ultraviolet/blue light; and, on the back side of the thin quartz layer 110, the optical component with the stacked photodetection layers 140 and 150 is configured to detect green/red light. Further, each p-i-n-i-p configuration includes a wide-bandgap perovskite p-i-n diode and a narrow-bandgap perovskite n-i-p diode. In one embodiment, the p-i-n-i-p configurations in the tetrachromatic perovskite image sensor 100 can be formed using inorganic halide perovskites. For example, the stacked layers of the tetrachromatic perovskite image sensor 100 includes a first halve: ITO/NiO/CsPbBrI₂/SnO₂/CsPbBr₃/NiO/ITO; a second halve: ITO/NiO/CsPbClBr₂/SnO₂/CsPbCl₃/NiO/ITO; and a Quartz between the first and second halves.

In one embodiment, the tetrachromatic perovskite image sensor 100 is at least configured in a stack composed of ITO/NiO/CsPbBrI₂/SnO₂/CsPbBr₃/NiO/ITO/Quartz/ITO/NiO/CsPbClBr₂/SnO₂/Cs PbCl₃/NiO/ITO. Each material serves as a layer in the stack configuration. Each layer is directly connected and in contact with adjacent layers, forming interfaces between different materials. These interfaces facilitate interactions between the materials.

FIG. 1B shows a fabrication process of a tetrachromatic perovskite image sensor according to some embodiments of the present invention. The fabrication process includes steps S10, S12, S14, S16, S18, S20, S22, S24, S26, S28, S30.

In step S10, ITO (indium tin oxide) layers 202 and 204 are formed on opposite surfaces of a quartz 200, so as to form an ITO-patterned quartz.

In step S12, NiO layers 208 and 210 are formed by sputtering NiO on double sides of the structure and in contact with the ITO layers 202 and 204.

In steps S14 and S16, photodetection layers 212 and 214 are formed on double sides of the structure and in contact with the NiO layers 208 and 210. In this stage, PbX₂ and CsX are sequentially deposited on the double sides and then an annealing process is performed. In one embodiment, an annealing temperature for the annealing process ranges from 250° C. to 300° C.; for example, at 280° C. The photodetection layers 212 and 214 have different characters, such as different compositions for sensing different wavelengths.

In step S18, SnO₂ layers 216 and 218 are formed by sputtering SnO2 on double sides of the structure and in contact with the photodetection layers 212 and 214.

In steps S20 and S22, a photodetection layer 220 is formed on an upper side of the structure and in contact with the SnO₂ layer 218. In this stage, PbCl₂ and CsCl are sequentially deposited on the upper side and then an annealing process is performed. In one embodiment, an annealing temperature for the annealing process is in a range from 250° C. to 300° C.; for example, at 280° C. The photodetection layers 212, 214, and 220 have different characters, such as different compositions for sensing different wavelengths.

In step S24, NiO and ITO electrodes 222 and 224 are formed on the photodetection layer 220 by at least one sputtering process. In one embodiment, the NiO and ITO electrodes 222 and 224 collectively have optical transparent property, so an incident light beam is allowed to pass through the NiO and ITO electrodes 222 and 224.

In steps S26 and S28, a photodetection layer 226 is formed on a bottom side of the structure. In this stage, PbI₂ and CsBr are sequentially deposited on the bottom side and then an annealing process is performed. In one embodiment, an annealing temperature for the annealing process ranges from 250° C. to 300° C.; for example, at 280° C. The photodetection layers 212, 214, 220, and 226 have different characters, such as different compositions for sensing different wavelengths; for example, the photodetection layers 212, 214, 220, and 226 are configured to sense light in green, blue, ultraviolent, and red wavelength intervals, respectively.

In step S30, NiO and ITO electrodes 228 and 230 are formed beneath the photodetection layer 226 by at least one sputtering process. In one embodiment, the NiO and ITO electrodes 228 and 230 collectively have optical transparent property, so an incident light beam is allowed to pass through the NiO and ITO electrodes 228 and 230. Moreover, optical reflection on the NiO and ITO electrodes 228 and 230 was reduced due to the optical transparent property.

In some embodiments, the photodetection layer 212 is a CsPbBr₃ layer, the photodetection layer 214 is a CsPbClBr₂ layer, the photodetection layer 220 is a CsPbCl₃ layer, and the photodetection layer 226 is a CsPbBrI₂ layer.

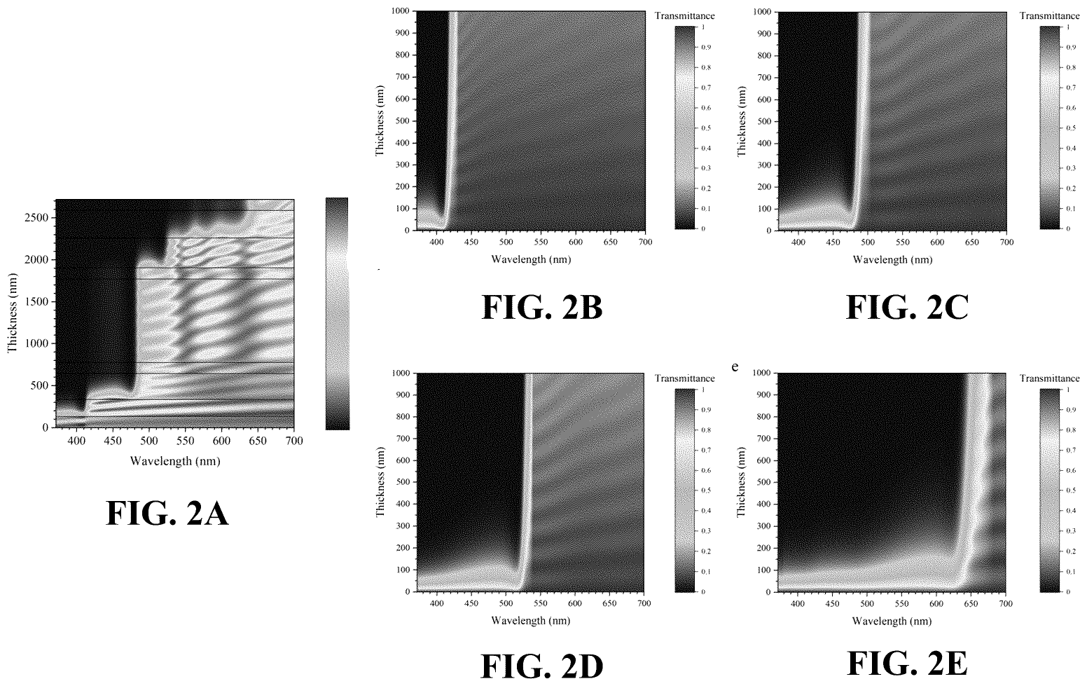

To theoretically estimate the distribution of optical intensity and photo absorption for the device design of the tetrachromatic perovskite image sensor, simulation for the optical properties of all the photodetection layers is provided as FIG. 2A, a graph for transmittance simulation within the depth of an entirety of the tetrachromatic perovskite image sensor. The required complex refractive indices (n, k) are obtained from ultraviolet-visible spectroscopy (UV-vis) and spectroscopic ellipsometry. Further, FIG. 2B, FIG. 2C, FIG. 2D, and FIG. 2E are graphs for transmittance simulation with respect to CsPbCl₃, CsPbClBr₂, CsPbBr₃, and CsPbBrI₂ thin films, respectively. Correspondingly, the graphs provide the optical simulation of the transmittance of four photoactive perovskite layers as a function of film thickness. Due to the sensor's stacked architecture, the lower layers require as much light intensity as possible to achieve high responsivity, thus creating a trade-off between colour selectivity and device performance in the whole tandem system. In one embodiment, it is determined that the transmittance should be below 0.5% across the entire detection range to avoid crosstalk in light discrimination.

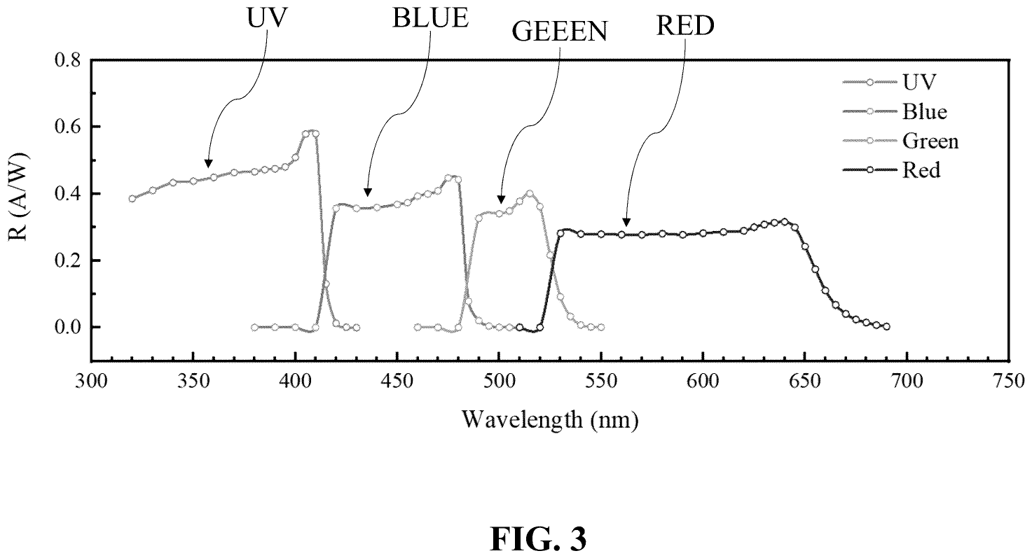

FIG. 3 shows a graph for the responsivity of the tetrachromatic perovskite image sensor as a function of wavelength according to some embodiments of the present invention. The tetrachromatic perovskite image sensor of the present invention demonstrates a wavelength-response range, relative responsivity to the normalized pigment absorbance, as well as an avian vision system that responds to wavelengths from 300 nm to 410 nm (ultraviolet wavelength interval), 410 nm to 485 nm (blue wavelength interval), 485 nm to 520 nm (a green wavelength interval), and 520 nm to 650 nm (red wavelength interval), functioning as UVRGB color photodetectors. The different photodetection layers in the tetrachromatic perovskite image sensor are configured to detect/sense those wavelength intervals, respectively.

Device working mechanism and performance characterizations are provided below:

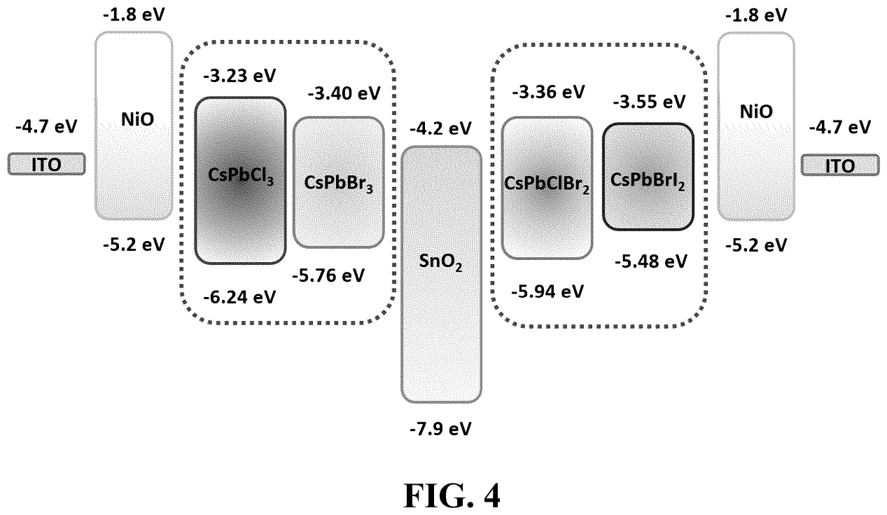

FIG. 4 depicts a schematic drawing for the energy level alignment of a tetrachromatic perovskite image sensor according to some embodiments of the present invention. To discriminate the four spectral colors, two p-i-n-i-p structures are provided, as illustrated by the energy level alignment without bias in the illustration of FIG. 4. Tetrachromatic perovskite image sensor has various layers/materials, in which lowest unoccupied molecular orbital (LUMO) and Highest Occupied Molecular Orbital (HOMO) of each layer/material are listed and expressed in the illustration of FIG. 4.

A p-i-n-i-p configuration with SnO₂, CsPbCl₃, and CsPbClBr₂ can be used for detecting ultraviolet and blue light. Another p-i-n-i-p configuration with SnO₂, CsPbBr₃, and CsPbBrI₂ can be used for detecting green and red light. In one embodiment, each p-i-n-i-p configuration includes a wide-bandgap perovskite p-i-n diode (e.g., ultraviolet light or green light) and a narrow-bandgap perovskite n-i-p diode (e.g., blue light or red light). NiO can serve as electron transport layer (ETL) material and is formed as an electron transport layer. The reason for selecting metal oxide as the ETL material is the large valence band offset (ΔEᵥ₁ and ΔEᵥ₂) between the perovskite layer and the n-type semiconductor. This offset acts as a hole barrier, preventing hole injection and electron-hole recombination at the perovskite-ETL interface. ITO can serve as electrode (e.g., an optical transparent electrode) or contact so an external bias source can be connected the image sensor and for applying a bias to the tetrachromatic perovskite image sensor via ITO.

When the tetrachromatic perovskite image sensor works or in an image sensing task, a forward or reverse bias is applied to the two side electrodes (e.g., ITO electrodes), activating one diode and deactivating the other within the p-i-n-i-p configuration to distinguish short- and long-wavelength light signals. Specifically, photogenerated carriers are more likely to separate under reverse bias and recombine under forward bias in the photodiode-mode photodetector.

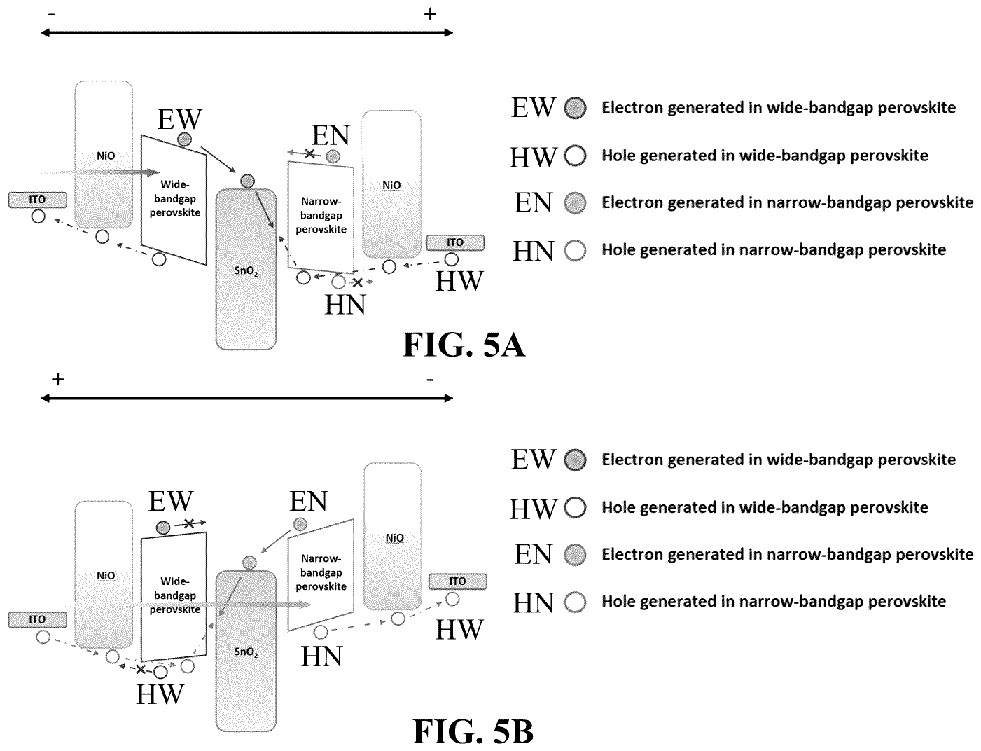

FIG. 5A and FIG. 5B illustrate the working mechanism of a tetrachromatic perovskite image sensor according to some embodiments of present invention. In the illustration of FIG. 5A and FIG. 5B, there are four types in labelling: EW is electron generated in wide-bandgap perovskite; HW is hole generated in wide-bandgap perovskite; EN is electron generated in narrow-bandgap perovskite; HN is hole generated in narrow-bandgap perovskite. Incident surface is the left side, so incident light is propagated to the wide-bandgap perovskite and then narrow-bandgap perovskite.

As depicted in FIG. 5A, when a reverse bias is applied to the tetrachromatic perovskite image sensor, the NiO/CsPbCl₃ (CsPbBr₃)/SnO₂ diode is under reverse bias, while the SnO_{2/}CsPbClBr₂ (CsPbBrI₂)/NiO diode is under forward bias. The photodetection layer (i.e., perovskite layer) of the p-i-n diode serves as the photoactive layer, generating photogenerated carriers. After electron-hole pairs separate, holes are collected at the ITO electrode, while electrons drift towards the interface between the other perovskite layer and the ETL (e.g., NiO layer), where a significant number of holes accumulate due to the large valence band offset. Electrons then recombine with holes. In contrast, the n-i-p diode functions as a conduction layer, and no photocurrent is generated, even if long-wavelength light produces photogenerated carriers. This is because these carriers cannot separate and transfer due to band-bending under forward bias. As such, short-wavelength light (i.e., wide bandgap) is detected.

Conversely, as depicted in FIG. 5B, long-wavelength light (i.e., narrow bandgap) is detected when a forward bias is applied.

The working mechanism of the tetrachromatic perovskite image sensor in the illustration of FIG. 5A and FIG. 5B is with respect to ultraviolet and blue light. The identical or similar operation can be applied to green and red light.

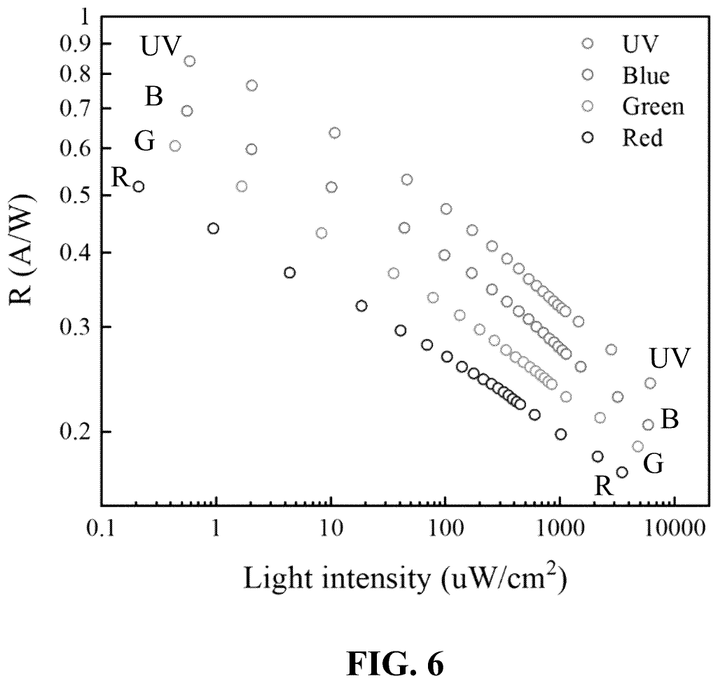

FIG. 6 shows a graph for responsivity of a tetrachromatic perovskite image sensor as a function of incident light intensity under 405 nm, 450 nm, 520 nm, and 635 nm light source according to some embodiments of the present invention. The optoelectronic properties of the tetrachromatic perovskite image sensor are further investigated using four single-wavelength lasers corresponding to UVRGB light at 405 nm (UV for ultraviolet), 450 nm (B for blue), 520 nm (G for green), and 635 nm (R for red). As demonstrated by FIG. 6, R values (A/W) are presented as a light intensity function ranging from ˜0.2 μW/cm² to ˜6 mW/cm². The maximum R (for responsivity) values at 405, 450, 520, and 635 nm are reported as 0.842, 0.694, 0.606, and 0.518 A/W under the light intensity of 0.586 μW/cm², 0.555 μW/cm², 0.437 μW/cm², 0.210 μW/cm², respectively. It is assumed that the dark current is dominated by shot noise and measured it under a working bias.

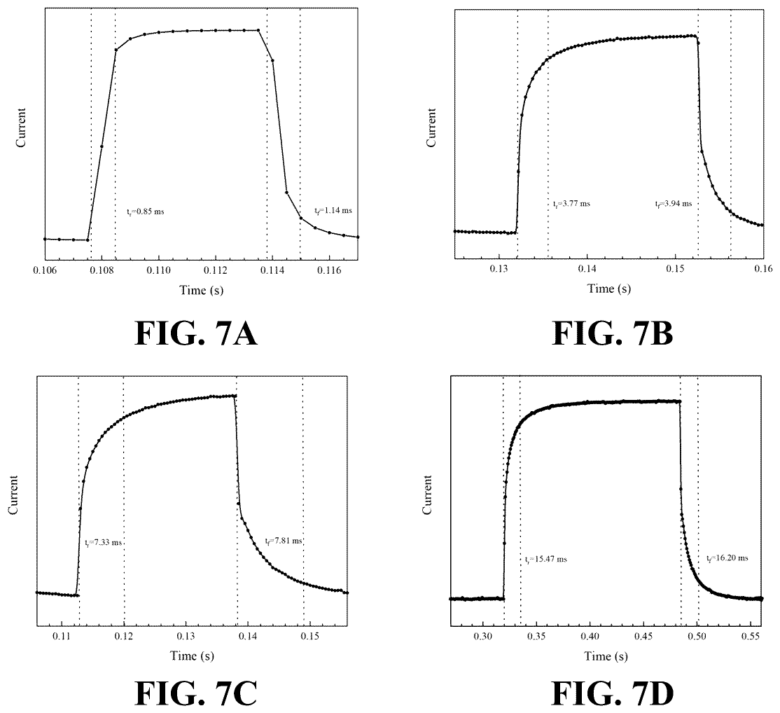

FIG. 7A, FIG. 7B, FIG. 7C, and FIG. 7D show graphs for the response time of four photodetection layers (i.e., photo active layers), in which FIG. 7A represents that for CsPbCl₃; FIG. 7B represents that for CsPbClBr₂; FIG. 7C represents that for CsPbBr₃; and FIG. 7D represents that for CsPbBrI₂. The tests are under 405 nm, 450 nm, 520 nm, and 635 nm light sources, respectively. The photoresponse rise time (τᵣ) and fall time (τ_{f}) are critical parameters for image sensor integration, as their frame rates depend on the response times of these diodes. As illustrated in FIG. 7A, FIG. 7B, FIG. 7C, and FIG. 7D, the response times for all photodetection layers (i.e., photoactive layers) range from 0.85 to 16.2 ms, increasing as the thin films' thickness increases.

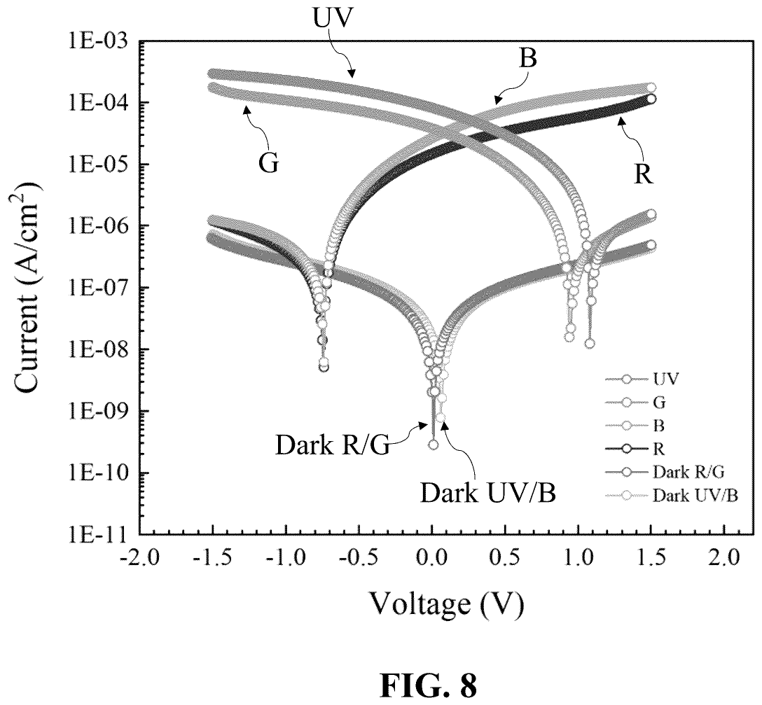

FIG. 8 shows a graph for J-V characterizations of a tetrachromatic perovskite image sensor under dark and single wavelength illuminations according to some embodiment of the present invention. The current density-voltage (J-V) curves are displayed in the illustration, which reveal that the UV/G diode and B/R diode can operate under forward and reverse bias, respectively. Given that the open-circuit voltage (Voc) increases with light intensity as a logarithmic function, the opted is for relatively high light intensities for function demonstration. Considering the aforementioned mechanism and J-V measurements, in one embodiment, −1.0 V and 1.2 V are selected as the working biases to obtain stable photoresponse currents and minimal noise from other photoactive layers.

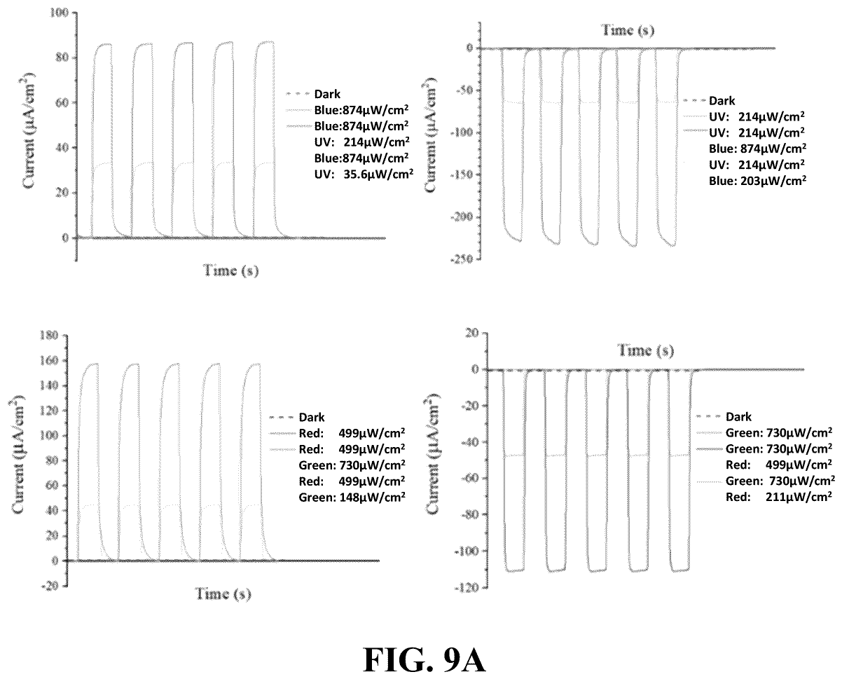

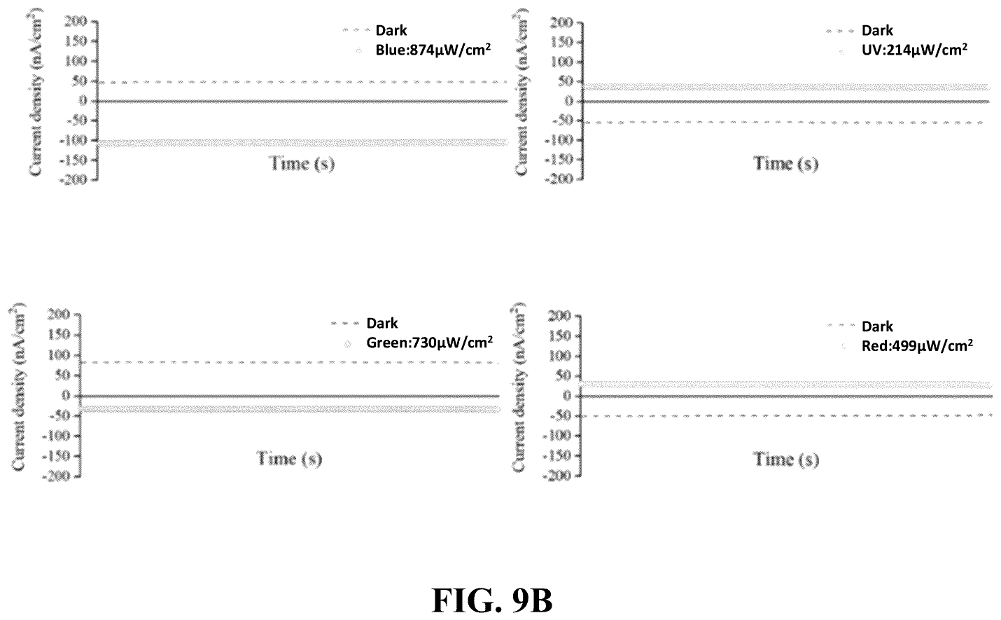

FIG. 9A shows graphs for photocurrent response of mixed light source of 405 nm, 450 nm, 520 nm and 635 nm at forward and reverse working mode. FIG. 9B shows graphs for the device's current density under dark and light conditions. To understand the color selectivity of the four wavelength ranges mentioned earlier, an additional color discrimination test is conducted, as displayed in the illustrations of FIG. 9A and FIG. 9B. The mixing light sources of UV/B and G/R activate the device separately at the given bias. Remarkably, although the current always flows in the opposite direction to the main current, indicating that few photogenerated charges separate and cross the band-binding barrier, the low current density of interference can be disregarded.

Further tetrachromatic color discrimination and extreme environment imaging demonstration are provided.

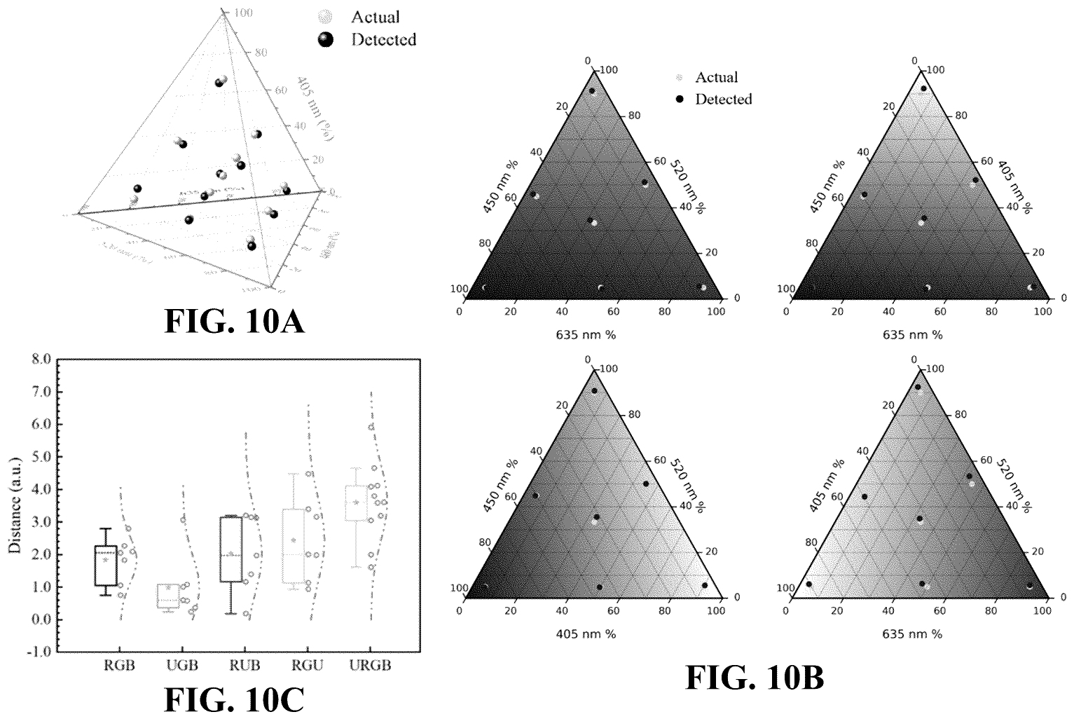

FIG. 10A illustrates the mixed light discrimination capability of the tetrachromatic perovskite image sensor system, with a tetrahedral light combination map based on 405 nm, 450 nm, 520 nm, and 635 nm light sources. FIG. 10B shows the ternary light combination map, also based on 405 nm, 450 nm, 520 nm, and 635 nm light sources, highlighting the sensor's ability to discriminate between different light source combinations. FIG. 10C displays the standard deviation of five maps, indicating the deviation between the actual and detected light combinations after calculation.

This biomimetic image sensor allows us to reconstruct the tetrahedral colour space for representing spectral and non-spectral colours. Notably, no luminance information is included in this colour space. To gain an intuitive understanding of the device's discrimination capabilities and eliminate chromatic aberration from light sources, absolute light intensities and relative intensity ratios are measured using 405, 450, 520, and 635 nm single-wavelength lasers as light sources. The light intensities are modulated to control the combinations.

In FIG. 10A and FIG. 10B, each pair of black and white scatter points in 3D

tetrahedral and ternary images are close, indicating that the reconstructed light combinations closely resemble the original light ratios. The variation between actual and detected values are evaluated, as shown in FIG. 10C. The results reveal larger deviations for four light sources compared to three and for R/G diodes compared to U/V diodes. This phenomenon is likely caused by the light intensity calibration, as well as significant scattering and reflection when light passes through multiple-layer interfaces.

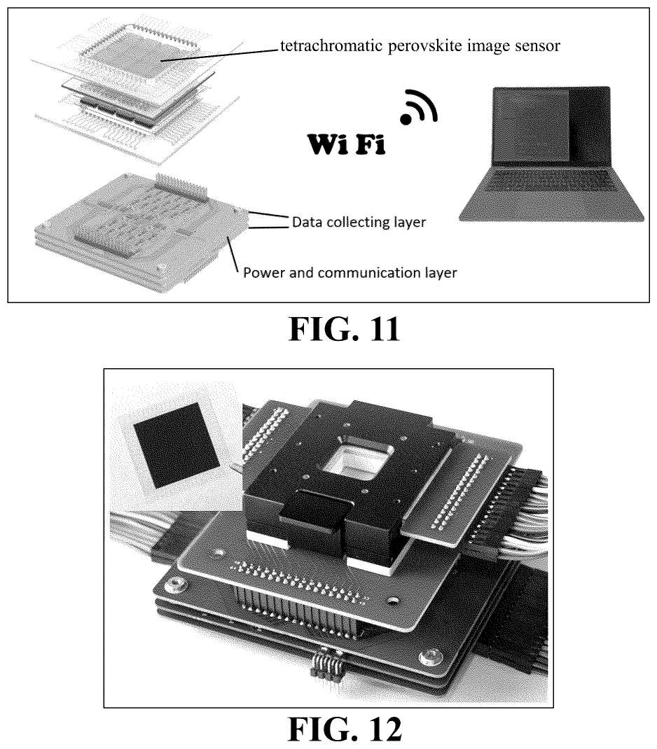

FIG. 11 illustrates a schematic diagram for a tetrachromatic perovskite image sensor system connected to a computer according some embodiments of the present invention. FIG. 12 illustrates an image of a tetrachromatic perovskite image sensor system, in which the insert image is the device without read-out circuit. To demonstrate the imaging capabilities of a tetrachromatic perovskite image sensor under various extreme conditions, a 4×32×32-pixel image sensor system (with a pixel line width of 100 μm and a pixel pitch of 400 μm) was fabricated, integrating on-chip read-out circuits, temperature sensors, and pressure sensors.

The tetrachromatic perovskite image sensor system includes a tetrachromatic perovskite image sensor, data collecting layers, and a power and communication layer for communicating with an external machine (e.g., computer) via a wireless channel. The tetrachromatic perovskite image sensor has a configuration as afore-described. The data collecting layers are responsible for capturing and processing output signals from the image sensor, converting them into digital data for further analysis. The power and communication layer provides power supply to other components for the system and facilitates wireless data transmission to external devices, enabling remote control and monitoring. For example, the digital data provided by the data collecting layers can be transmitted to external devices by the power and communication layer.

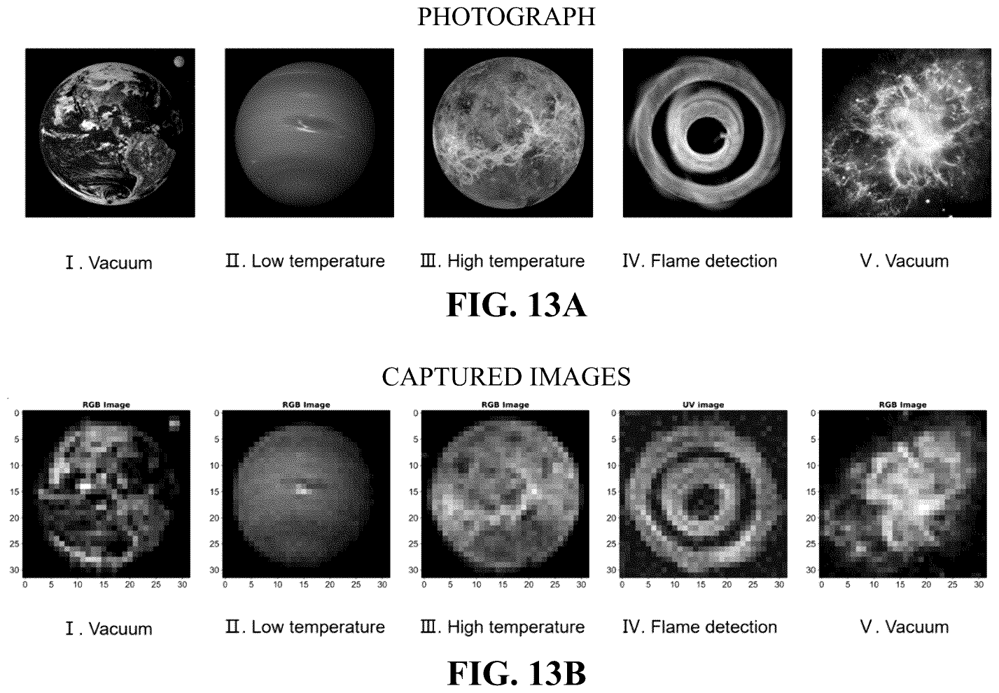

FIG. 13A and FIG. 13B show photographs and captured images of Earth (I), Neptune (II), Venus (III), flame (IV), and Crab Nebula (V) in ambient, vacuum, low temperature, high temperature, and vacuum environments. Notably, the fuel stove emblazoned the flame, and the projector projected other pictures. The calculated output image of flame detection was UV channel, while other images were RGB channel. The system is tested in vacuum, low-temperature, and high-temperature environments, using images of Earth, Neptune, and Venus from the National Aeronautics and Space Administration (NASA) to simulate the space environment. Additionally, an image of the Crab Nebula from NASA is used as the control target in the ambient environment. Due to the scarcity of UV sources in daily life, the image sensor is placed above a fuel stove, which emits UV radiation in a high-temperature environment. The UV, B, G, and R channels are displayed separately to assess the image quality of each channel.

As discussed above, all-vacuum processes are used for device fabrication. The four photoactive materials are entirely inorganic. The electron transport layer (ETL) and hole transport layer (HTL) used in the device are also inorganic. In terms of the device's optical design, the optical properties of all layers are simulated, and the appropriate film thicknesses for detecting a four-wavelength range are selected. This enables the imager to discriminate between mixed light from UV to visible light. Accordingly, perovskite materials are employed to achieve four-color detection and image reproduction. Additionally, the functional integration of the perovskite color image system is demonstrated, showing its capability to operate under harsh environments.

The functional units and modules of the apparatuses and methods in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

All or portions of the methods in accordance to the embodiments may be executed in one or more computing devices including server computers, personal computers, laptop computers, mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A tetrachromatic perovskite image sensor, comprising:
a quartz layer;
a first perovskite p-i-n-i-p component disposed on a first side of the quartz layer and configured to detect ultraviolet and blue light, wherein the first perovskite p-i-n-i-p component comprises two photodetection layers for detecting an ultraviolet wavelength interval and a blue wavelength interval, respectively;
a second perovskite p-i-n-i-p component disposed on a second side of the quartz layer and configured to detect green and red light, wherein the second perovskite p-i-n-i-p component comprises two photodetection layers for detecting a green wavelength interval and a red wavelength interval, respectively;
a first optical transparent electrode disposed on the first side of the quartz layer; and
a second optical transparent electrode disposed on the second side of the quartz layer, so as to apply bias to the first perovskite p-i-n-i-p component and second perovskite p-i-n-i-p component with the first optical transparent electrode collectively.

2. The tetrachromatic perovskite image sensor of claim 1, wherein, in the first perovskite p-i-n-i-p component, the photodetection layer for the ultraviolet wavelength interval is a CsPbCl₃ layer, and the photodetection layer for the blue wavelength interval is a CsPbClBr₂ layer.

3. The tetrachromatic perovskite image sensor of claim 2, wherein, in the second perovskite p-i-n-i-p component, the photodetection layer for the green wavelength interval is a CsPbBr₃ layer, and the photodetection layer for the red wavelength interval is a CsPbBrI₂ layer.

4. The tetrachromatic perovskite image sensor of claim 3, further comprising ITO layers, NiO layers, and SnO₂ layers, so as to form a configuration in a stack composed of ITO/NiO/CsPbBrI₂/SnO₂/CsPbBr₃/NiO/ITO/Quartz/ITO/NiO/CsPbClBr₂/SnO₂/Cs PbCl₃/NiO/ITO.

5. The tetrachromatic perovskite image sensor of claim 4, wherein, in the stack, each material layer is in contact with an adjacent layer to form a material interface.

6. The tetrachromatic perovskite image sensor of claim 3, wherein the ultraviolet wavelength interval at least spans from 300 nm to 410 nm, the blue wavelength interval at least spans from 410 nm to 485 nm, the green wavelength interval at least spans from 485 nm to 520 nm, and the red wavelength interval at least spans from 520 nm to 650 nm.

7. The tetrachromatic perovskite image sensor of claim 1, wherein the first perovskite p-i-n-i-p component comprises a CsPbCl₃ layer, a CsPbClBr₂ layer, a first NiO layer, a second NiO layer and a SnO₂ layer, wherein the first NiO layer, the CsPbCl₃ layer, and the SnO₂ layer collectively form a NiO/CsPbCl₃/SnO₂ diode, and wherein the SnO₂ layer, the CsPbClBr₂ layer, and the second NiO layer collectively form a SnO₂/CsPbClBr₂/NiO diode.

8. The tetrachromatic perovskite image sensor of claim 1, wherein the second perovskite p-i-n-i-p component comprises a CsPbBr₃ layer, a CsPbBrI₂ layer, a first NiO layer, a second NiO layer and a SnO₂ layer, wherein the first NiO layer, the CsPbBr₃ layer, and the SnO₂ layer collectively form a NiO/CsPbBr₃/SnO₂ diode, and wherein the SnO₂ layer, the CsPbBrI₂ layer, and the second NiO layer collectively form a SnO₂/CsPbBrI₂/NiO diode.

9. A tetrachromatic perovskite image sensor system, comprising:
the tetrachromatic perovskite image sensor of claim 1;
at least one data collecting layer configured to capture and process output signals from the tetrachromatic perovskite image sensor and to convert them into digital data; and
a power and communication layer providing power supply and facilitating wireless data transmission to an external device for enabling remote control and monitoring, wherein the digital data provided by the data collecting layer is transmitted to the external device by the power and communication layer.

10. A method for manufacturing a tetrachromatic perovskite image sensor, comprising:
providing an ITO-patterned quartz;
forming a first photodetection layer for detecting a blue wavelength interval and a second photodetection layer for detecting a green wavelength interval on an upper side and a bottom side of the ITO-patterned quartz, respectively;
forming a third photodetection layer for detecting an ultraviolet wavelength interval on the upper side of the ITO-patterned quartz after forming the first photodetection layer and the second photodetection layer; and
forming a fourth photodetection layer for detecting a red wavelength interval on the bottom side of the ITO-patterned quartz after the forming the third photodetection layer, wherein the first photodetection layer, the second photodetection layer, the third photodetection layer, and the fourth photodetection layer are inorganic halide perovskites.
